(19) United States
(12) Patent Application Publication
(10) Pub. No.: US 2026/0040863 A1
(43) Pub. Date: Feb. 5, 2026

(54) Enhanced Atomic Layer Etching Process with Optimized Gas Flow Control for Semiconductor Manufacturing

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/791,471

(22) Filed: Aug. 1, 2024

(51) Int. Cl. H01L 21/67; H01J 37/32

(52) U.S. Cl. CPC H01L 21/67069; H01J 37/32449; H01J 37/32082; H01J 2237/332; H01J 2237/334

(57) ABSTRACT

Disclosed herein is an enhanced atomic layer etching (ALE) process for semiconductor manufacturing, focusing on improved gas flow control. It introduces a method of maintaining constant inert gas flow for both surface modification and sputtering steps, significantly reducing gas exchange time, and improving cycle efficiency. Key to this innovation is the pre-determined, fixed set points for mass flow controllers (MFCs) and the valve, streamlining operations and ensuring consistent production quality.

### BACKGROUND OF THE INVENTION

### 1. Field of the Invention

The present invention pertains to the field of semiconductor manufacturing, more specifically to atomic layer etching (ALE) apparatus and processes used in the fabrication of semiconductor devices. It focuses on innovations in the control and management of gas flow within the ALE process, aiming to enhance efficiency, accuracy, and throughput in semiconductor etching applications.

### 2. Description of the Prior Art

Reactive ion etching (RIE) is a predominant technology in semiconductor manufacturing. In RIE, diverse species including neutrals, radicals, and ions concurrently influence the etching process. A key characteristic of RIE is the synergistic interaction between ion and neutral fluxes, which significantly enhances the etching rate. This synergistic effect was first described by Coburn and Winters in “Ion—and electron-assisted gas-surface chemistry—an important effect in plasma etching,” published in J. Appl. Phys., vol. 50, pages 3189-3196 (1979). They reported increased silicon etching rates when using an argon ion beam, a XeF2 neutral beam, and their combination. Further, Gottscho et al., in “Microscopic uniformity in plasma etching” (J. Vac. Sci. Technol., B10, pages 2133-2147, 1992), developed a model to quantify this synergy for the etching rate ER:

$$ER = \frac{υ {E}_{i} {J}_{i}}{1 + ( υ {E}_{i} {J}_{i} ) / ( {υ}_{n} {sJ}_{n )}} ,$$

where U represents the volume removed per unit bombardment energy for a saturated surface (cm³/eV), Eᵢ the ion energy (eV), Jᵢ the ion flux to the surface (cm²/s), vₙ the volume removed per reacting neutral (cm³), Jₙ the neutral flux to the surface and s the sticking probability of the neutral species on the bare surface.

Achieving effective RIE necessitates the presence of both ion and neutral fluxes to exploit the synergy identified by Coburn and Winters. However, it is increasingly complex in modern etching apparatus to balance these fluxes, particularly for etching high aspect ratio structures with dimensions shrinking to nanometer scale. Uniform results across 300 mm wafers and consistent repeatability in production pose additional challenges.

Over the past several decades, advancements in etching apparatus features have been made to enhance uniformity. For instance, the evolution of plasma sources from a single coil (U.S. Pat. No. 4,948,458 to Ogle) to multiple coils (U.S. Pat. No. 6,164,241 to Chen et al.) has been notable, either in the form of inductively coupled plasma (ICP) or transformer coupled plasma (TCP). Additionally, gas injection techniques have improved, incorporating multiple injection points to ensure a uniform plasma within the vacuum reactor, as described in U.S. Pat. No. 8,231,799 to Bera et al. and 10,825,659 to Treadwell. Further enhancements include optimizing the electrostatic chuck (ESC) to feature multiple zones with independently adjustable temperatures (U.S. Pat. No. 9,713,200 to Pease and 10,056,225 to Gaff et al.).

A radio frequency (RF) power generator, coupled to the ESC, provides a bias for the ions in the plasma in addition to the plasma sheath. This coupling, facilitated through a blocking capacitor, helps establish a stable plasma sheath by preventing electron flow to the ground, as detailed in U.S. Pat. No. 5,302,240 to Hori et al. Moreover, various pulsing schemes for RF power generators have been implemented to improve ion energy and angular momentum distribution, thereby maximizing the synergetic effects between ions and neutrals, as described in U.S. Pat. No. 8,264,154 to Banner et al. and 10,121,639 to Kanarik. RF power generators with tailored waveforms, as discussed by Wang et al. in “Experimental demonstration of multifrequency impedance matching for tailored voltage waveform plasmas” (J. Vac. Sci. Technol. A37, 021303, pages 1-11, 2019), have also been employed to precisely control ion energy.

Additionally, gases can be pulsed in a cyclic process to enhance performance, as disclosed in U.S. Pat. No. 10,121,639 to Kanarik. This cyclic approach segments the RIE process into steps, each optimized with a different set of process gases.

Despite these improvements, achieving the required uniformity across a 300 mm wafer for critical dimension (CD), loading, and profile remains a significant challenge, often entailing considerable expense.

ALE has been developed to address the limitations of RIE. ALE apparatus has evolved from the RIE apparatus with less stringent requirements for achieving uniformity on a 300 mm wafer. However, ALE has unique requirements due to the nature of its process steps.

An overview of ALE technology is presented by Karanik et al. in “Overview of atomic layer etching in the semiconductor industry” (J. Vac. Sci. Technol. A33, pages 020802 1-14, 2015), and further discussed in a book by Lill, “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and material removal. The modification creates a thin reactive layer with a defined thickness, which is easier to remove than the unmodified material. The removal step eliminates this modified layer while preserving the underlying substrate, thus resetting the surface for subsequent cycles. The material removal is quantified over multiple cycles and can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process.

The anisotropic ALE process, which is the focus of the present invention, has been employed for etching various materials, demonstrating the technology's versatility:
Si and Ge as described in U.S. Pat. No. 10,727,073 to Tan et al.,
SiO2 as described in U.S. Pat. No. 9,620,382 to Oehrlein et al.,
C as described in U.S. Pat. Pub. Nos. 2017/0316935 and 2022/0216050 by Tan et al.,
W as described in U.S. Pat. Pub. No. 2020/0286743 from Lai et al and U.S. Pat. No. 10,096,487 to Yang et al,
Co as described in U.S. Pat. No. 10,096,487 to Yang et al,
Ru as described in U.S. Pat. Pub. No. 2022/0199422 by Yang et al.,
Other refractory metals and materials with high surface binding energy as described in U.S. Pat. No. 11,450,513 to Yang et al.,
Cu as described in WO Pat. Pub. No. 2022/046429 by Yang et al.,
GaN and other III-V materials as described in U.S. Pat. No. 10,056,264 to Yang et al.,
MRAM as described in U.S. Pat. No. 10,749,103 to Tan et al.,
EUV patterning as described in U.S. Pat. No. 9,922,839 to Wise et al., and
Surface smoothing of various materials as described in U.S. Pat. No. 10,304,659 to Karanik et al.

It should also be noted that a deposition component in the ALE steps or an independent deposition step is often introduced in the ALE process to enhance its performance, especially for controlling the profile of structures being etched. For example, selective deposition on a carbon-containing material is applied to improve ALE performance as described in U.S. Pat. Pub. No. 2017/0316935 by Tan et al. Additionally, as disclosed in U.S. Pat. No. 9,805,941 to Karanik et al., atomic layer deposition (ALD) and ALE are conducted from a single plasma chamber. This method involves sequentially alternating between ALE and ALD processes to prevent feature degradation during etching, improve selectivity, and encapsulate sensitive layers of a semiconductor substrate.

The distinct chemistry, speciation, and plasma energy composition involved in the surface modification and sputtering steps enhance the process by enabling more controlled ion, electron, and neutral species fluxes, thereby widening the process window. This separation facilitates self-limiting reactions, crucial for maintaining the ideality of the etching process-characterized by uniformity, smoothness, and selectivity. Karanik et al. in “Predicting synergy in atomic layer etching” (J. Vac. Sci. Technol. A35, pages 05C302 1-7, 2017) defined ALE synergy as:

$${ALE}_{synergy} S ( \% ) = \frac{EPC - ( α + β )}{EPC} \times 100 \%$$

EPC is “etch per cycle” representing the total thickness of material removed in one cycle, typically averaged over many cycles. The values of “α” and “β” are (undesirable) contributions from the surface modification step and the sputtering step, respectively. Ideally, synergy will approach 100% with no etching from either step alone. In practice, RIE in the surface modification step are nonzero because of presence of ions in the plasma which generates neutrals to modify the surface. In the sputtering step, physical sputtering of underlying unmodified layer is also nonzero.

It is desirable for the plasma in the surface modification step of the ALE process to be free from ion bombardment. However, the unintended introduction of RIE components during this step presents a persistent challenge. This issue stems from the difficulty in completely preventing ion bombardment of the substrate surface, compromising the ideality of the ALE processes. Modern ALE methodologies struggle to effectively eliminate these RIE components, leading to suboptimal etching outcomes, particularly as device geometries become more complex and smaller in scale. The presence of RIE components in ALE processes can result in non-uniform layer removal and undesirable etching profiles, which are especially problematic in advanced device manufacturing where even minor deviations can significantly impact device performance and yield.

One solution to this problem, as disclosed in U.S. Pat. No. 9,362,131 to Agarwal et al., involves using an electron beam source. During the passivation step (surface modification step), a remote plasma source supplies passivation species to the main process chamber while keeping ion energy below the etching threshold. During the etching operations, the flow from the remote plasma source is stopped, and the ion energy is raised above the etch threshold. This approach introduces an additional remote source. It complicates the apparatus and may increase the cost of the process.

In addition to tackling challenges related to achieving higher synergy in ALE, efforts have been made to enhance the speed of the ALE process. For instance, high-energy ions, more than 150 eV, are used to remove the modified surface layer as disclosed in U.S. Pat. No. 10,763,083 to Yang et al. Furthermore, pulsing has been applied to an RF power generator coupled to the electrostatic chuck (ESC) to provide a bias for the ions in the plasma. In another development disclosed in WO Pat. Pub. No. 2023/183129, the sputtering time in the sputtering step has been reduced to a range between 10 ms and 600 ms.

Another approach to increasing the speed of ALE involves relaxing the requirements for self-limiting reactions, as disclosed in TW Pat. No. 1757334 to Cottle et al. While this method accelerates the ALE process, it may reduce the synergy factor, thereby degrading the performance of ALE.

The standard practice in ALE involves modulating multiple gases' flow rates using mass flow controllers (MFCs). This modulation is typically dynamic, requiring constant adjustments to maintain optimal etching conditions, which adds complexity and potential for inconsistency in the etching process. Additionally, the transitioning between different etching steps, such as from surface modification to sputtering, often necessitates complete gas exchanges, further prolonging the overall process cycle time.

Moreover, the reliance on frequent adjustments for gas flow rates and valve positions during production runs leads to inefficiencies and variations in process outcomes. These factors limit the throughput and scalability of conventional ALE processes, posing a bottleneck in high-volume semiconductor manufacturing.

It is in this context, there is a clear need for innovations in the ALE process that streamline gas management, reduce cycle times, and enhance the consistency of etching outcomes. The present invention addresses these needs by introducing novel methods for gas flow control and set point determination, improving the efficiency and reliability of ALE processes in semiconductor manufacturing.

### SUMMARY

This patent application reveals various embodiments in ALE apparatus and process, focusing on specific innovations that significantly enhance operational efficiency.

A typical ALE process utilizes a first process gas to modify substrate surface and a second process gas to generate energetic ions to remove modified layer. A principal innovative feature of this invention lies in the consistent flow of the second process gas throughout the ALE process. In some embodiments, this approach maintains a constant flow rate of the second process gas, eliminating the need for frequent gas exchanges. This innovation is pivotal in improving the cycle time of the ALE process by substantially reducing gas exchange durations, a typical bottleneck in conventional ALE systems.

Additionally, the application emphasizes another critical advancement in the development and application of set points for the MFCs and the valve. In various implementations, these set points are meticulously determined during the process development phase and are subsequently kept fixed during production runs. This strategy streamlines the operation, ensuring consistent performance while negating the need for continual adjustments during production. Such a method not only simplifies the operational complexity but also contributes to the reliability and efficiency of the ALE process.

In some embodiments, the ALE process system further integrates advanced control mechanisms for the MFCs and the valve. These mechanisms enable precise control over gas flow rates, essential for maintaining optimal etching conditions. The integration of a constant gas flow regime, coupled with fixed set points for critical components, represents a significant leap in ALE process technology.

In conclusion, the key innovations detailed in this patent application—maintaining a constant flow of the second process gas and determining fixed set points for the MFC and valve during process development—are instrumental in enhancing the efficiency and consistency of ALE processes. These advancements, applied in various embodiments and implementations, signify a notable evolution in the field, paving the way for more streamlined and effective ALE operations.

### BRIEF DESCRIPTIONS OF DRAWINGS

In order to provide enhanced clarity, the following description references the accompanying drawings:

FIG. 1A illustrates an exemplary process system for ALE.

FIG. 1B is a schematic representation of a valve with a movable part to modulate gas conductance through a pump.

FIG. 1C is an exemplary functional diagram of an MFC.

FIG. 2A illustrates waveforms of the plasma source and the bias unit.

FIG. 2B showcases waveforms of the gases of an ALE process.

FIG. 3 presents a flowchart of an exemplary ALE process with a constant second process gas flow.

### DETAILED DESCRIPTIONS

To ensure comprehensive understanding, this section delves into detailed embodiments of the present invention. Although certain specifics are provided for clarity, modifications and variations that align with the subsequent claims are deemed appropriate. Conventional methods and components are highlighted to underscore the distinct features of the invention.

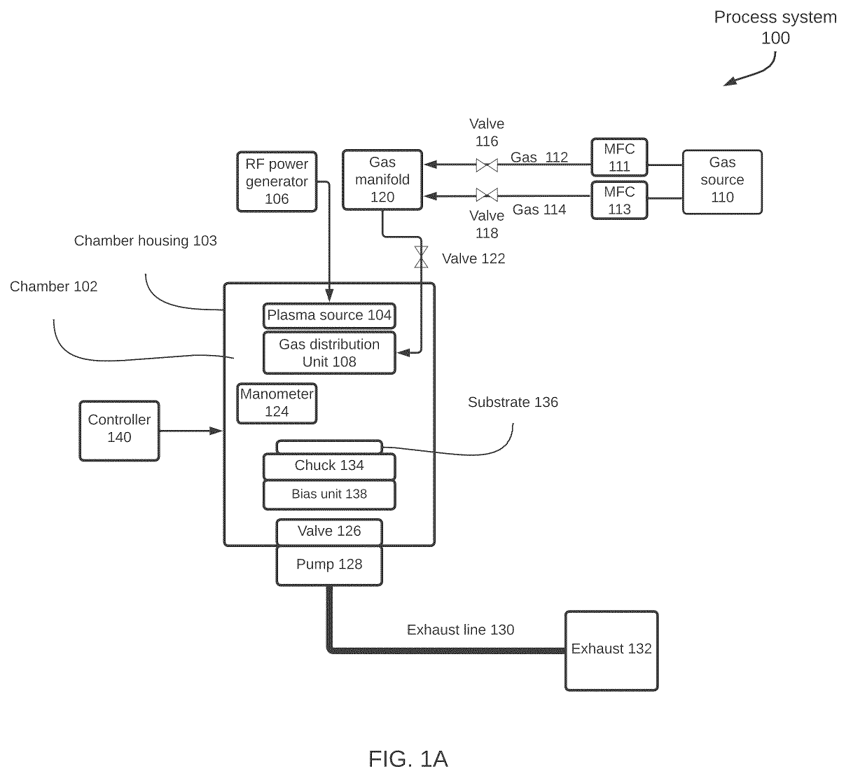

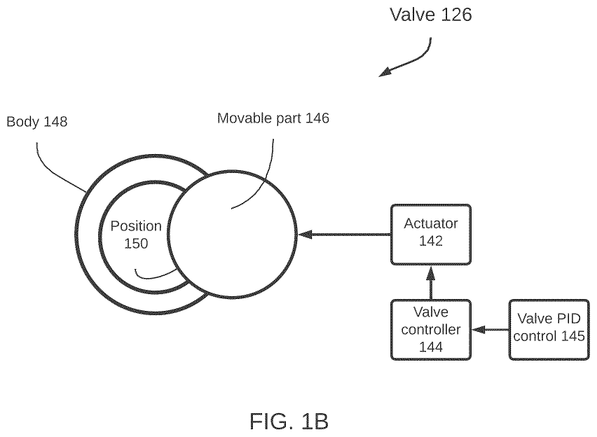

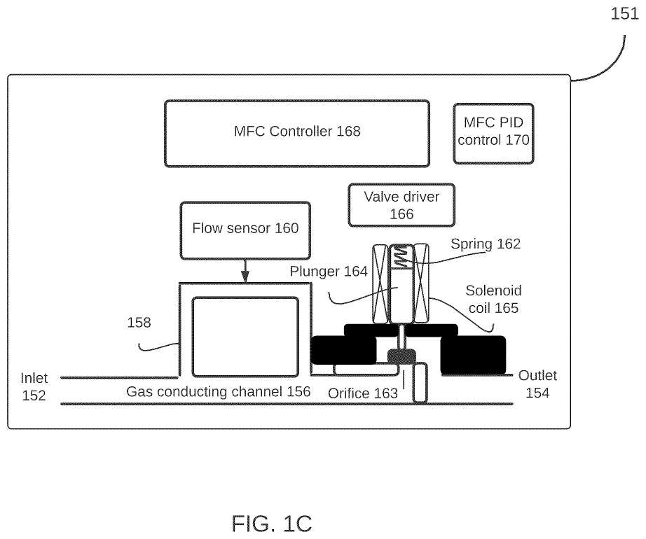

FIG. 1A presents an exemplary process system for ALE, designated as 100. This process system incorporates a chamber, referred to as 102. The operations within chamber (102) are coordinated by a controller, identified as 140. Enclosing chamber (102) is a chamber housing, marked as 103, which establishes a vacuum environment suitable for plasma processing. The chamber housing (103) may be constructed from materials such as aluminum or quartz, with the aluminum interior surface undergoing specific treatments to enhance resistance to the plasma environment. These treatments may include anodization.

Affixed atop chamber housing (103) is a plasma source, labeled as 104. Beneath the plasma source (104), and not depicted in the figure, is a window that hermetically seals chamber (102). This window may be composed of materials such as quartz or ceramics, with its interior surface potentially coated with a plasma-resistant material like yttrium oxide. Plasma source 104, which can take various forms including but not limited to a multiple turn coil, may be shaped cylindrically or conically.

Plasma source (104) is functionally connected to an RF power generator, denoted as 106. The RF power generator (106) can generate RF power at single or multiple frequencies. These frequencies include, but are not limited to, 100 kHz, 200 kHz, 400 kHz, 2 MHz, 13.56 MHZ, 27 MHz, 40 MHz, and 60 MHz. The RF power generator (106) is typically coupled to a resonator (not shown in the Figure). The resonator is responsible for matching the output impedance of the RF power generator (106) to the RF impedance from the chamber (102), considering the influence of transmission lines.

A gas distribution unit, referred to as 108, is connected to a gas manifold, designated as 120. The gas source, marked as 110, supplies at least a first process gas (112) and a second process gas (114) to the gas manifold (120). For a silicon ALE process, the first process gas is typically chlorine, while the second process gas could be argon or helium. Along the path of the first process gas (112), a MFC (111) is utilized to control the flow rate of the gas. This MFC operates by measuring the gas flow rate and adjusting it using proportional-integral-derivative (PID) control. A valve (116) is positioned in the path of the first process gas to enable or disable its flow. In certain implementations, this valve (116) can divert the first gas to an alternative pathway when not in use. Similarly, for the second process gas (114), a corresponding MFC (113) and a valve (118) are optionally installed in its path. An additional valve (122) may be placed optionally between the manifold (120) and the gas distribution unit (108) to control the gas flow into chamber (102).

The gas source (110) may encompass various gas delivery mechanisms, such as a gasbox. Depending on the specific embodiment, the gas distribution unit (108) can function either as an injector or as a showerhead. In some implementations, the injectors may be placed in a center position. In some other implementations, some injectors may be placed along sidewall of the chamber (102). In some configurations, the window is integrated with the gas distribution unit (108), serving as a showerhead while simultaneously sealing chamber (102). A manometer, designated as 124, is used to measure the pressure inside chamber (102). The controller (140) determines the frequency of these pressure measurements and uses the rate of pressure change within the chamber to ascertain if a steady-state pressure condition has been achieved. Additionally, chamber (102) includes a pump (128) and a valve (126). The pump (128), which could be a turbo molecular pump (TMP) in some implementations, is employed to extract unused gases and reaction byproducts from chamber (102), expelling them through an exhaust line (130) to an exhaust (132). The position of a movable part of the valve (126) is critical for determining the rate of gas extraction in combination with the pump (128). In one implementation, the movable part is a movable cover. It should be noted that the movable cover is employed here for illustrating the inventive concept. The valves can be implemented in various forms as known in the art. For example, the valves include but are not limited to gate valves, butterfly valves, ball valves, and diaphragm valves. Each type has a different design of the movable part. The movable part is movable by an actuator controlled by a driving current as a set point.

As schematically illustrated in FIG. 1B, an exemplary valve, labeled as 126, includes a body (148) consisting of an opening, and a movable part (146). The position (150) of the part (146) is pivotal in determining the gas conductance through modulating size of the opening, which works in conjunction with the capacity of the pump (128). To adjust the part's position (150), an actuator (142), governed by a valve controller (144), is employed. The valve controller (144) utilizes a valve PID control (145) to establish the required position for maintaining steady state chamber pressure according to the set point, in collaboration with the controller (140). Typically, it takes a few hundred milliseconds for the valve PID control to position the valve (126) appropriately, which is a limiting factor in the cycle time of the ALE process, particularly during gas exchanges. Addressing this bottleneck is considered desirable for process efficiency.

The controller (140) operates the MFCs, the pump (128), and the valve (126) to maintain the steady state chamber pressure, as measured by the manometer (124).

FIG. 1C depicts a schematic diagram of an exemplary MFC, denoted as 151. This MFC (151) includes an inlet (152) and an outlet (154), interconnected by a gas-conducting channel (156). A proportional valve, not shown in the Figure, diverts a portion of the gas into a channel (158). The flow sensor (160) coupled to this channel, typically using thermal sensing, measures the flow rate based on temperature differences at two specific points along the flow path. This measured flow rate serves as an indicator of the overall flow rate in channel (156).

The MFC also includes a solenoid valve featuring a spring (162) that maintains a plunger (164) in position. The gas conductance across orifices (163) is determined by the position of this plunger (164). When the plunger obstructs the channel within orifice (163), the gas flow is halted. The solenoid coil (165) controls the position of the plunger (164), with the magnetic force generated by the current in the coil, coupled with the force from the spring (162), determining the plunger's position.

The flow sensor (160) transmits its readings to a MFC controller (168), which compares these readings to a preset value representing the desired gas flow rate. Should there be a discrepancy between the actual and desired flow rates, the controller (168) directs the valve driver (166) to adjust the current in the coil (165), thus altering the plunger's position. This adjustment process continues until the flow rate aligns with the target. To speed up this process, the MFC controller (168) employs a MFC PID control (170). However, this adjustment can still take several hundred milliseconds, which is less than ideal for ALE processes.

In certain embodiments of the invention, the set points for the MFCs and the valve (126) are established during a recipe development phase. In one implementation, the set points for the MFCs include drive currents for the plungers. The set points for the valve may include drive currents for the actuator (142) in the valve (126) which is used to move the part (146).

These set points are stored in a storage medium. The set points for the MFCs may be related to type of gases and to a specific MFC. The set points for the valve may also depend on the specific valve being used.

When the recipe is utilized for production, the PID controls (170) for MFCs are deactivated, markedly reducing the operational time of the MFC. Applying current to the coil (165) rapidly positions the plunger (164) correctly. While some gas is still diverted to channel (158) for monitoring by the flow sensor (160), this monitoring mainly serves as a confirmation to ensure consistency with the desired flow rate.

In a manner analogous to the MFC settings, the position (150) of the movable part of the valve (126) is also determined during the recipe development phase. Once the ALE process is initiated for production runs, this valve position remains fixed, significantly reducing the time required to establish a steady-state chamber pressure when the ALE process recipe is repetitively deployed for processing many substrates.

Additionally, chamber (102) incorporates a chuck, identified as 134, which serves as a support structure for a substrate, indicated as 136. The chuck (134) may be configured in various forms, including but not limited to an electrostatic chuck (ESC) or a vacuum chuck. A bias unit (138) is connected to the chuck (134) to provide a bias to both the chuck and the substrate. This bias is instrumental in enhancing ion energy as needed during the process.

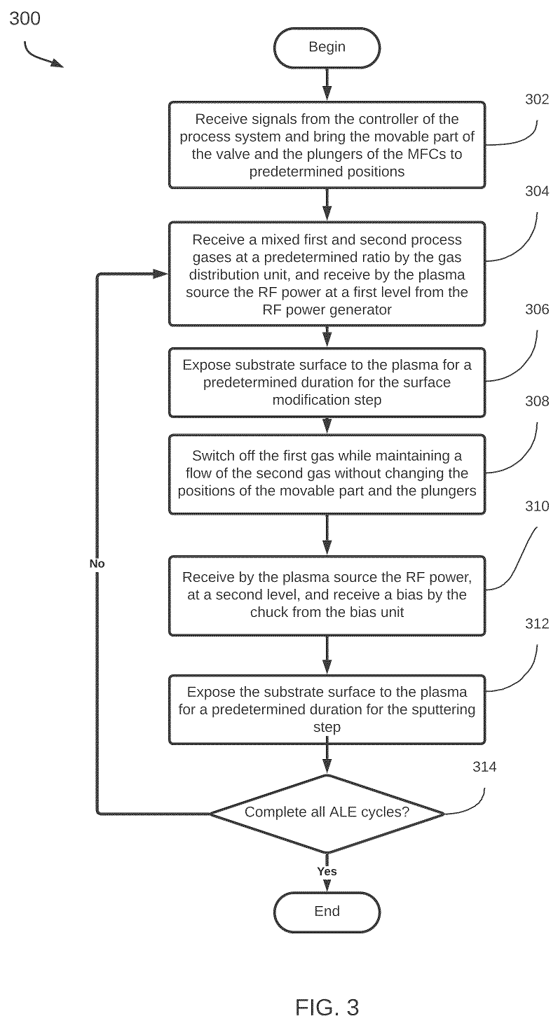

An exemplary ALE process, marked as 300, is illustrated in FIG. 3. This process 300 begins with step 302, wherein the controller (140) sends signals to the valve controller (144) to move the part (146) of the valve (126) to its predetermined position (150). The setting points for the actuator (142) have been determined during the recipe development phase. The PID control (145) is deactivated and is not used, which reduce the setting time for the cover position. At the same time, the controllers (168) of the MFCs receive the signals from the controller (140) and apply predefined currents to the coils of the MFCs (165). These settings, established during ALE process development, are stored in the storage medium of the controller (140), or alternatively, in the valve controller and MFC controller, respectively. The process then advances to a surface modification step starting at step 304. Here, a mixture of the first and second process gases is delivered to the gas distribution unit (108) from the gas manifold (120). The mixing ratio of these gases is dictated by the set points of MFC 111 and MFC 113. For instance, in silicon etching using ALE, a chlorine and argon mixture is delivered to the gas distribution unit (108) for surface modification. The chlorine to argon ratio may range from 5:1 to 100:1, with a preferable ratio exceeding 10:1. A modest percentage of argon aids in plasma ignition in chamber (102) during the surface modification step, as chlorine, being an electronegative gas, poses challenges in ignition. However, the quantity of argon is kept minimal to prevent argon ion bombardment on the substrate surface, thereby preserving the ideal characteristics of the ALE process.

Following the delivery of mixed gases to chamber (102), the controller (140) monitors changes in chamber pressure measured by the manometer (124) to determine if a steady state has been achieved. The chamber pressure is measured at predetermined intervals—for instance, every millisecond, five milliseconds, or ten milliseconds. The controller (140) calculates the pressure difference between successive measurements. If the measured difference falls below a set target, it is concluded that a steady state chamber pressure has been established.

Upon achieving the steady state chamber pressure, the plasma source (104) receives RF power at a first level from the RF power generator (106). At step 306, the substrate (136) undergoes exposure to the plasma for a predetermined duration. The neutrals, including radicals, modify the substrate's surface (136), forming a layer with weakened chemical bonds. In the context of silicon etching using ALE, this layer consists of silicon bonds weakened due to chlorine adsorption on the surface.

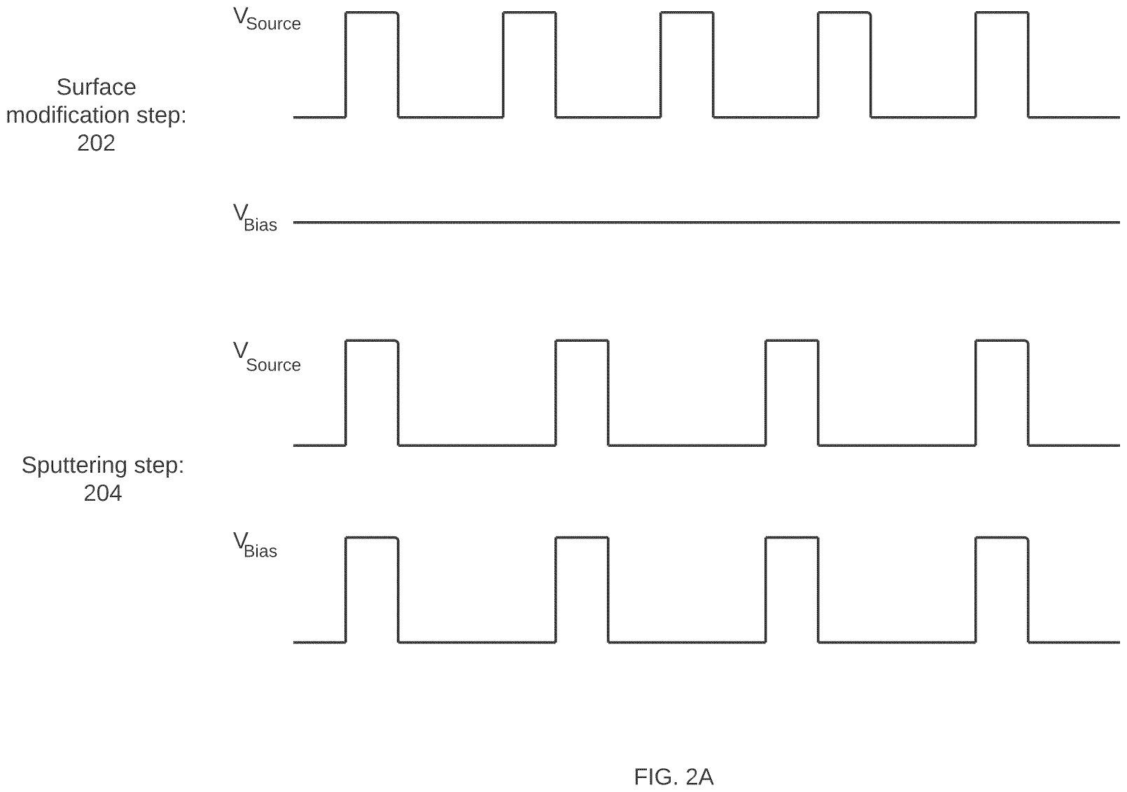

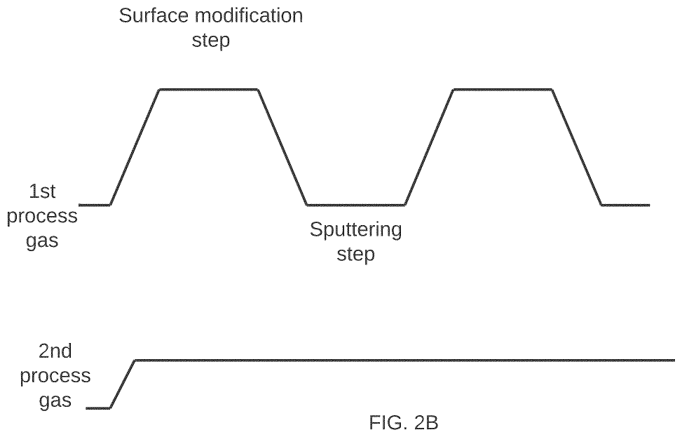

At step 308, the ALE process transitions from the surface modification step (202) to a sputtering step (204), as depicted in FIGS. 2A and 2B. Waveforms for the plasma source (104) and the bias unit (138) are illustrated in FIG. 2A, while FIG. 2B demonstrates the exchange of the process gases. During this transition at step 308, the first process gas (112) is ceased by valve (116), but the flow of the second process gas (114) into chamber (102) continues uninterrupted. Notably, in this process, neither the set points for MFC 113 nor for valve (126) are altered, in line with the present invention. This innovative approach minimizes the transition time associated with the process gas exchange, significantly improving the ALE cycle time. Subsequently, at step 308, the controller (140) utilizes the manometer (124) to monitor the chamber pressure as per process 324 until a new steady state is established, predominantly with the second process gas (114). The steady state chamber pressure for the sputtering step is expected to be lower than that of the surface modification step due to the cessation of the first process gas. This lower pressure is preferable to attain higher ion energy with a tighter energy and angular distribution.

Advancing to step 310, the plasma source (104) receives RF power at a second level once the new steady state chamber pressure is reached. Concurrently, a bias is applied to chuck (136) to further increase ion energy. In one implementation, the bias unit is an RF power generator capable of producing single or multiple frequencies, coupled to the chuck (136) via a resonator, as commonly known in the art. Alternatively, the bias unit (138) may be a tailored waveform generator, designed to achieve a tight ion energy distribution. Then, at step 314, the substrate (136) is subjected to ions from the plasma generated by the second process gas for a predetermined duration. This exposure removes the modified layer formed during the surface modification step.

As exemplified in FIG. 2, pulsing schemes can be employed to enhance ALE performance. For example, during the surface modification step, the RF power supplied to plasma source (104) might be pulsed to reduce ion bombardment on the substrate surface. During the sputtering step, plasma source (104) and bias unit (138) can be pulsed in a synchronized fashion, as is known in the art. The pulsing schemes as highlighted are examples only. There are many different ways to pulse plasma source and the bias as known in the art. All these variations should fall into the inventive concept of the present invention.

Finally, at step 314, the controller (140) determines whether all ALE cycles are completed to conclude the process 300.

1. A process system for performing ALE process, comprising:
a chamber maintaining an interior space for a vacuum environment;
a plasma source coupled to an RF power generator configured to generate plasma in the chamber;
a bias unit operatively connected to a chuck;
a gas distribution unit configured to receive at least a first process gas with a first MFC and a second process gas with a second MFC from a gas source; and
a controller configured to operate the process system in steps including a surface modification step and a sputtering step sequentially, wherein the controller operates the gas distribution unit for receiving the first and the second process gases with predetermined flow rates at the surface modification step, and wherein the controller further operates the gas distribution unit for ceasing receiving the first process gas at the sputtering step, with the second gas flow remaining constant for said steps.

2. The process system of claim 1, wherein a set point for a valve which controls gas extraction rate from the chamber remains unchanged throughout the ALE process.

3. The process system of claim 2, wherein the set point determines a movable part of the valve, wherein a position of the movable part influences extraction rate of the gases from the chamber.

4. The process system of claim 1, wherein set points of the first and the second MFCs remain unchanged throughout the ALE process.

5. The process system of claim 1, wherein PID controls are deactivated for the first and the second MFCs.

6. The process system of claim 2, wherein the set point is determined by the controller during a recipe development phase.

7. The process system of claim 1, wherein the process system further includes a manometer for measuring pressures inside the chamber.

8. The process system of claim 7, wherein the pressures are measured at predetermined time intervals, and a steady-state chamber pressure is achieved if the pressure difference between two successive measurements is less than a predetermined value.

9. The process system of claim 8, wherein the controller is further configured to trigger an operation of delivering RF power either from the RF power generator and/or from the bias unit based upon achieving the steady-state chamber pressure.

10. The process system of claim 1, wherein the gas distribution unit further includes an injector placed in a central position of a top part of the chamber.

11. The process system of claim 1, wherein the gas distribution unit further includes a plurality of side injectors along sidewall of the chamber.

12. The process system of claim 1, wherein the gas distribution unit further includes a showerhead.

13. The process system of claim 1, wherein the bias unit further includes a tailored waveform generator.

14. A method of performing an ALE process in a process system comprising:
a. moving by an actuator a movable part for a valve associated with a pump to a position according to a predetermined set point, wherein the position is fixed for the ALE process including at least a surface modification step, and a sputtering step, wherein the position of the movable part influences gas extraction rate from a chamber;
b. receiving a mixed first and second process gases at predetermined flow rates by a gas distribution unit, and receiving by a plasma source a first RF power from a RF power generator;
c. exposing a substrate surface to a plasma generated in a chamber for a first predetermined duration, wherein the substrate is placed on a chuck;
d. switching off the first process gas while maintaining the flow rate of the second process gas, wherein the position of the movable part, and set points of a first and a second MFCs for the process gases are unchanged, wherein the first process gas is switched off by a valve placed between the first MFC and the gas distribution unit;
e. receiving by the plasma source a second RF power from the RF power generator, and receiving a bias by the chuck from a bias unit;
f. exposing the substrate surface for a second predetermined duration; and
g. repeating steps a to f to complete the ALE process.

15. The method of claim 14, wherein the method further includes a step of deactivating PID controls for the first and the second MFCs.

16. The method of claim 14, wherein the method further includes a step of determining the position of the movable part of the valve by the controller during the recipe development phase.

17. The method of claim 14, wherein the method further includes a step of measuring pressures inside the chamber, wherein the pressures are measured in accordance with a predetermined time intervals, thereby a steady state chamber pressure is achieved if the pressure difference between two successive measurements is less than a predetermined value.

18. The method of claim 17, wherein the method further includes a step of delivering RF power either from the RF power generator and/or from the bias unit triggered by achieving the steady state chamber pressure.

19. The method of claim 14, wherein said gas distribution unit further includes an injector placed in a center position of a top part of the chamber.

20. The method of claim 14, wherein said gas distribution unit further includes a plurality of injectors along sidewall of the chamber.
